(19) United States
(12) Patent Application Publication
(10) Pub. No.: US 2013/0291929 A1
(43) Pub. Date: Nov. 7, 2013

(54) LONG-LIFE OPTICAL CONCENTRATOR BASED ON A SPECIFIC FRESNEL LENS PRODUCED FROM POLYMERIC MATERIALS FOR SOLAR POWER GENERATION

(71) Applicants: Uwe Numrich, Gross-Zimmern (DE); Thomas Arndt, Luetzelbach (DE); Peter Battenhausen, Brachttal (DE); Jochen Ackermann, Muehltal (DE); Michael Olbrich, Karlstein (DE)

(72) Inventors: Uwe Numrich, Gross-Zimmern (DE); Thomas Arndt, Luetzelbach (DE); Peter Battenhausen, Brachttal (DE); Jochen Ackermann, Muehltal (DE); Michael Olbrich, Karlstein (DE)

(73) Assignee: Evonik Roehm GmbH, Darmstadt (DE)

(21) Appl. No.: 13/980,460

(22) PCT Filed: Jan. 26, 2012
(86) PCT No.: PCT/EP2012/051210

§ 371 Date: Jul. 18, 2013

Related U.S. Application Data
(60) Provisional application No. 61/437,220, filed on Jan. 28, 2011.

(30) Foreign Application Priority Data
Jan. 28, 2011 (DE) 102011003311.4

(51) Int. Cl. G02B 19/00; H01L 31/058; B29D 11/00

(52) U.S. Cl. CPC G02B 19/0014; B29D 11/00269; H01L 31/058; G02B 19/0042
USPC 136/248; 264/1.7; 359/361

(57) ABSTRACT

The present invention relates to a concentrator for focusing solar radiation, having surface structuring in the form of one or more Fresnel lenses on the lower side, and to the production thereof from polymeric materials by means of a specific extrusion process. The inventive concentrator can be employed in plants utilizable for photovoltaic or solar heating purposes, and has the required durability and performance in demanding climatic zones. The inventive concentrator enables particularly economic production and efficient concentration of solar radiation onto objects such as solar cells or absorber units, irrespective of the geometry thereof. The inventive concentrator has high longevity and—combined with this—high optical performance when employed in extreme and demanding climatic zones. This relates, for example, to the area of a high-performance solar cell used in concentrating photovoltaics, and likewise to an absorber tube which finds use in concentrating solar thermal collector, for example in the context of parabolic trough technology.

### FIELD OF THE INVENTION

The present invention relates to a concentrator for focusing solar radiation, having surface structuring in the form of one or more Fresnel lenses on the lower side, and to the production thereof from polymeric materials by means of a specific extrusion process. The inventive concentrator can be employed in plants utilizable for photovoltaic or solar heating purposes.

The inventive concentrator enables particularly economic production and efficient concentration of solar radiation onto objects such as solar cells or absorber units, irrespective of the geometry thereof.

The inventive concentrator has high longevity and—combined with this—high optical performance when employed in extreme and demanding climatic zones.

This relates, for example, to the area of a high-performance solar cell as used in concentrating photovoltaics, and likewise to an absorber tube which finds use in concentrating solar thermal collectors, for example in the context of parabolic trough technology.

### STATE OF THE ART

Fresnel lenses are a development from the early 18th century and are used in projection monitors, overhead projectors, floodlights, for example headlights for automobiles, lighthouses and similar fields of use. Recently, Fresnel lenses have also been finding use as concentrators for solar energy (especially photovoltaics) for focusing and subsequent conversion of the solar energy to electricity.

In order to ensure performance in relation to the precision of the concentration of the solar radiation, and also strength, dimensional stability and easy installability of such plates or films with optical elements such as the Fresnel lenses in the solar applications described, it is necessary according to the prior art to laminate or to bond these structured films onto a supporting film or plate. However, such a process regime is associated with high costs. In addition, quality and longevity are at risk or limited due to potential weak points and potential adverse interactions with the adhesive system used.

Alternatively, what is called “thermolamination” can be used, which can optionally be configured inline. The high temperatures and pressures required for this purpose lead, however, to destruction or damage to the optical structures, as a result of which the precision—necessary in the applications envisaged—of the concentration of the solar radiation cannot be maintained.

Inline lamination is disclosed in U.S. Pat. No. 5,945,042 and in U.S. Pat. No. 6,375,776 for thin carrier films with a thickness of 10 to 100 μm or of 35 to 150 μm. Such thin films are unsuitable for dimensional stability reasons for employment in photovoltaics or solar thermal collectors.

The production of linear Fresnel lenses from an acrylate substrate is described in U.S. Pat. No. 5,656,209 as the coextrusion of a high-viscosity and of a low-viscosity melt to produce linear Fresnel lenses, using a three-roll mill. A disadvantage of this process is that the resulting optical structures are nonsharp or are not replicated accurately by the embossing tool and are thus unsuitable for the envisaged application for precise concentration of solar radiation. In addition, the resulting products do not have high UV stability, more particularly under demanding climatic conditions.

WO 2009/121708, in turn, discloses a process for thermolamination of a film having optical structures onto a polymer sheet without damaging the structures. However, lamination processes often have the disadvantage that the additional adhesive layers and the resulting increase in the number of phase inter-faces within the plate lead to an impairment of the optical properties and hence to an energy yield loss.

Moreover, the process costs are high and the required quality can only be produced to a very limited degree, if at all.

Furthermore, such prior art systems have to be actively cleaned. Such a plant is described, for example, in WO 2009028000.

A similar system disclosed in WO 2009/099331 has the disadvantage that it has an additional matrix with a flat lower edge above the Fresnel lenses, and a liquid filler. However, this additional material reduces transmission. Furthermore, this system can be produced only in a very costly and inconvenient manner.

Most prior art processes are aimed at producing Fresnel structures usually by means of lamination process, but this—as described—is associated with distinct quality and cost disadvantages.

None of the disclosures teach how the generally required specifications, consisting of 1. longevity, dimensional stability, 2. precision of concentration of solar radiation, 3. UV and weathering stability and 4. abrasion resistance of these films or plates, are achieved. Thus, delamination, clouding, bubble formation, scratches or yellowing often occur after only a short operating time.

### Problem

It was an object of the present invention to provide a novel concentrator for concentrating solar radiation, which has a particularly high efficiency within the lifetime envisaged and, at the same time, enables high-quality and inexpensive production. The inventive concentrator can be used in plants utilizable for photovoltaic or solar heating purposes.

At the same time, the concentrator must of course have a longevity of at least 20 years in demanding climatic zones, ensure high precision of concentration of solar radiation and have an improved resistance or at least equivalent resistance, compared to the prior art, with respect to environnmental influences and cleaning operations.

More particularly, it was an object of the present invention, especially with regard to the prior art, to provide a process with which particularly sharp surface embossments with long-lived dimensional stability can also be obtained on single-layer polymer sheets.

In addition, the concentrator obtained from the process should have self-supporting character.

In this document, the term “self-supporting” is understood to mean that a workpiece, after the curving or forming step, retains this form at use temperatures up to at least 50° C., preferably at least 65° C., and the ambient environmental conditions, for example wind speeds. In connection with concentrators for solar radiation, for example, this means that a geometry, once shaped, is maintained in the course of transport, installation and operation of the plant.

Further objects which are not stated explicitly are evident from the overall context of the description, claims and examples which follow.

### Solution

The object is achieved by a novel process for producing surface-structured, self-supporting concentrators, and the provision of such self-supporting concentrators for plants for solar power generation.

The object is more particularly achieved by provision of a novel process for producing a self-supporting concentrator for plants for solar power generation, and by this concentrator produced by the process according to the invention.

The process according to the invention consists of at least the following steps:

A high-transparency polymer layer is formed from a pellet formulation by melting in an extruder and withdrawing via a slot die to give a melt film or sheet. This melt is structured on the later lower side of the concentrator by means of a gravure-bearing cooled roll or drum which has a temperature gradient of at least 60° C. on the roll surface, and cooled in such a way that the structuring is still maintained. The structuring of the is an optical surface structure on the lower side of the concentrator, said optical surface structure forming one or more Fresnel lenses. It is additionally very important in accordance with the invention that the concentrator has been equipped with at least one UV absorber and at least one UV stabilizer.

Preferably, a second extruder is used to apply a second polymer layer by means of coextrusion before the structuring from a second pellet formulation on the upper side of the first polymer layer. More preferably, this second polymer layer has been equipped with the UV stabilizers and UV absorbers. Optionally, this second extruder or a further third extruder can be used to apply the second pellet formulation, likewise on the lower side of the first polymer layer, by means of coextrusion. This third layer preferably has identical additization to the second layer.

Additionally preferably, at least one UV absorber is a triazine, very particularly preferred UV absorbers being at least one benzotriazole and at least one triazine, and very particularly preferred UV stabilizers being at least one HALS compound.

It has been found that, surprisingly, a multilayer system produced in such a way does not have many disadvantages of the prior art. For instance, there is no risk of delamination. The process is notable for a high quality and precision of the prism sheets produced in such a way for the purpose effective of the concentration of solar radiation. The upper side of the sheet and optionally likewise the lower side have also been protected from strong UV radiation and hence from yellowing. By virtue of the selection of suitable materials, it is also possible with the process to avoid cloudiness or heat-related discoloration of the collector. Furthermore, it is possible, by virtue of an appropriate surface finish described below, to minimize the risk of scratching or soiling. This too leads to prolonging of the lifetime. Furthermore, with the aid of the by means of an antireflection coating, the energy yield can in principle be increased.

In addition, the upper side of the concentrator can be coated with a scratch-resistant and/or antisoil coating and/or an antireflection coating, before or after the structuring.

In general, the first polymer layer determines the stiffness and is therefore crucial for shaping. In another embodiment, it is, however, also possible that the difference in the layer thicknesses between the first polymer layer and the second or third polymer layer is low, and all or two layers contribute to shaping.

The inventive concentrator may have an overall thickness between 0.1 mm and 25 mm, preferably between 0.5 mm and 15 mm and more preferably between 1 mm and 10 mm.

A further aspect of the present process is that the laminate has such a stiffness that it is self-supporting, and that the laminate at the same time remains dimensionally stable under the action of heat and at the same time can be deformed with preservation of the Fresnel lens structure. This property is achieved in accordance with the invention by virtue of the individual polymer layers being matched to one another with regard to stiffness, thickness and other material properties.

In addition to the process according to the invention, concentrators which can be produced by means of this process also form part of the present invention.

More particularly, these are concentrators which are characterized in that the concentrator, viewed from the light source, consists of at least the following layers:

1. A second polymer layer which comprises a UV stabilizer and a UV absorber and has a thickness between 5 and 500 μm, preferably between 10 and 250 μm, and more preferably between 20 and 150 μm.

2. A first polymer layer having a thickness between 0.1 and 25 mm, preferably between 0.5 and 15 mm, and more preferably between 1 and 10 mm.

In addition the lower side of the concentrator has been surface-structured in the form of one or more Fresnel lenses.

The second polymer layer may also be a layer composed of several sublayers. For example, the second layer may be a two- or three-layer coextrudate. In this case, each individual layer may satisfy the thicknesses stated for the second layer. Preferably, however, the entire coextrudate has a thickness which corresponds to the values specified for the second polymer layer of between 5 and 500 μm, preferably between 10 and 250 μm and more preferably between 20 and 150 μm.

The production, preferably inline with the entire process for producing the concentrator, is effected by means of known coextrusion technologies, as detailed, for example, in “Plastic Extrusion Technology” (F. Hensen, Hanser Publishers, Munich, 2nd edition, 1997).

The inventive concentrator is preferably a concentrator which, viewed from the light source, consists of the following layers:

1. a surface finish with soil-repellent, antireflective and scratch resistance-improving properties,

2. a second polymer layer which comprises UV stabilizer and UV absorber and has a thickness between 5 and 500 μm, preferably between 10 and 250 μm and more preferably between 20 and 150 μm.

3. a first polymer layer with a thickness between 0.1 and 25 mm, preferably between 0.5 and 15 mm, and more preferably between 1 and 10 mm.

4. a third polymer layer which optionally and preferably comprises UV stabilizer and UV absorber and has a thickness between 5 and 500 μm, preferably between 10 and 250 μm, and more preferably between 20 and 150 μm.

For the third polymer layer, with regard to an optional multilayer structure, the same applies as already stated above for the second polymer layer.

In addition the lower side of the concentrator has been surface-structured in the form of one or more Fresnel lenses.

The individual Fresnal lenses may be angular, radial or linear structures. These may be arranged in grid or linear form, or irregularly with respect to one another, preference being given to arrangement of linear structures running parallel.

These inventive, novel concentrators have the following properties, in combination as an advantage over the prior art, particularly with regard to the optical properties: the material of the inventive concentrator is—under the influence of UV, weathering and moisture—particularly color-neutral and does not become cloudy. The concentrator exhibits an excellent weathering stability and, in the case of optional equipping with a surface finish, has a very good chemical resistance, for example to all commercial cleaning compositions. These aspects too contribute to preservation of solar focusing over a long period. In order to facilitate cleaning, the surface has soil-repellent properties. In addition, the surface is optionally abrasion-resistant, antireflective and/or scratch-resistant.

### DETAILED DESCRIPTION OF THE INVENTION

The Material of the Polymer Layers

The first polymer layer is a layer of transparent polymer materials, for example SAN (styrene-acrylonitrile terpolymer), polycarbonate, polyurethane, polycycloolefins, polystyrene, a styrene copolymer, a polyester, preferably polyethylene terephthalate (PET) or PETG, or of a poly(meth)acrylate.

The second, optional or the likewise optional third polymer layer, is a layer of poly(meth)acrylate, a fluoropolymer or a mixture of poly(meth)acrylate and a fluoropolymer, preferably a mixture of PMMA and PVDF or a multilayer system composed of PMMA and PVDF.

The polymer composition of two (in the case of a two-layer system) or of all three layers may optionally also be identical.

In general, the relevant wavelength range of the concentrating photovoltaics (PV) is approx. 300 to 1800 nm, or approx. 300 to 1200 nm in the case of use of crystalline silicon PV cells.

The selected polymers should have a maximum transparency in the particular relevant wavelength range.

The Surface Structuring

The surface of the high-transparency polymer layer is embossed with Fresnel lens structures by an inline embossing process with specific instruments. This involves feeding the melt from the slot die of the extruder(s) directly to a roll nip between intake roll and the gravure roll or drum. The melt is transported by means of the with a gravure roll or drum which produces the Fresnel lens shape. This roll or drum is at a controlled temperature of the heat of fusion or a maximum of 20° C. cooler at the contact site of the roll nip. After leaving the nip with the intake roll, the melt film is fed into a nip formed from the gravure roll or drum and a cooling water bath. At this point, the roll or drum has been cooled to such an extent that the melt film is cooled to the solidification temperature. For this purpose, the drum or roll may be hollow and filled with a cooling medium. The fill level should be selected such that only the region opposite the cooling bath is cooled. By virtue of this process, the melt film is cooled more slowly in the gravure operation to obtain a better and sharper structuring profile.

By virtue of this process, the melt film is cooled from a temperature between 150° C. and 250° C., generally between 180° C. and 220° C., within half a roll rotation, to a temperature of below 100° C., preferably of below 90° C. more preferably of below 80° C.

For this purpose, the surface of the gravure roll or drum is cooled within half a rotation, proceeding from the roll nip to which the melt is fed from the slot die, by at least 60° C., preferably by at least 80° C. and more preferably by at least 100° C.

In order to ensure constant cooling, the cooling medium, for example water, within the drum or roll and in the cooling water bath, is renewed regularly, preferably permanently, via inlets and outlets.

Furthermore, the gravure roll or drum is preferably notable in that a gravure sleeve has been clamped onto the cylinder.

The processes for surface structuring which can be employed in accordance with the invention can be read about in detail in WO2009/072929 and in WO01/19600.

The Stabilizer Package (Light Stabilizer)

The ideally used high-transparency polymer layer has been equipped with UV protection. Appropriate UV protection formulations can be found, for example, in WO 2007/073952 (Evonik Rohm) or in DE 10 2007 029 263 A1.

A particular constituent of the UV protection layer used in accordance with the invention is the UV additive package, which contributes to long life and to the weathering stability of the concentrators.

Ideally, the stabilizer package used in the UV protection layers used in accordance with the invention consists of the following components:
A: a UV absorber of the benzotriazole type,
B: a UV absorber of the triazine type,
C: a UV stabilizer, preferably an HALS compound.

Components A and B can be used as an individual substance or in mixtures. At least one UV absorber component must be present in the uppermost polymer layer. Component C is necessarily present in the uppermost polymer layer used in accordance with the invention.

More particularly, the concentrator produced in accordance with the invention is notable for its significantly improved UV stability compared to the prior art and the associated longer lifetime. The inventive material can thus also be used in solar concentrators over a very long period of at least 15 years, preferably even at least 20 years, more preferably at least 25 years, at sites with a particularly large number of sun hours and particularly intense solar radiation, for example in the south-western USA or the Sahara.

The wavelength spectrum of solar radiation relevant for “solar heating” ranges from approx. 300 nm to 2500 nm. The range below 400 nm, especially below 375 nm, should, however, be filtered out to prolong the lifetime of the concentrator, such that the “effective wavelength range” from 375 nm or from 400 nm to 2500 nm is preserved. The mixture of UV absorbers and UV stabilizers used in accordance with the invention exhibits stable, long-lived UV protection over a broad wavelength spectrum (approx. 300 nm-approx. 400 nm).

The Surface Coating

The term “surface coating” in the context of this invention is understood as a collective term for coatings which are applied to reduce surface scratching and/or to improve abrasion resistance and/or as an antisoil coating and/or to reduce reflections.

The Scratch-Resistant Coating

To improve the scratch resistance or the abrasion resistance, polysiloxanes, such as CRYSTALCOAT™ MP-100 from SDC Technologies Inc., AS 400-SHP 401 or UVHC3000K, both from Momentive Performance Materials, can be used. These coating formulations are applied, for example, by means of roll-coating, knife-coating or flow-coating to the surface of the high-transparency polymer layer of the concentrator. Examples of further useful coating technologies include PVD (physical vapor deposition) and CVD plasma (chemical vapor deposition).

The Antisoil Coating

Antisoil functionalities are often included in the formulation of the scratch-resistant coating. They can also be applied in place of the scratch-resistant coating or—in a separate process step—above the scratch-resistant coating. Antisoil coatings can be produced, for example—but not exclusively—by fluoropolymers, silicone polymers, so-called hybrid materials, titanium dioxide particles or combinations.

The Antireflection Coating

There are single-layer and multilayer antireflection coatings. Single-layer coatings generally have a refractive index which is calculated from the square root of the refractive index of the material below it. Multilayer coatings have different, graduated refractive indices. The choice of the correct antireflection coating arises from the optical properties of the material below it, especially the refractive index thereof, and from the adhesion properties of the layer below it and from the preferred wavelengths to be focused, which may be absorbed only to a minimal degree, if at all, by the coating. For this reason, antireflection coatings based on the principle of absorption are unsuitable for the inventive concentrators.

Commercially available antireflection coatings are known to those skilled in the art. The choice of the suitable coating will also be easy for a person skilled in the art with knowledge of the other parameters of the concentrator. In addition, such antireflection coatings for concentrators can be read about in US 20090032102.

In a further embodiment, the reflection can be reduced such that the two uppermost layers of the concentrator, for example the first and second polymer layers, or the scratch-resistant and/or antisoil coating and the second polymer layer, or the scratch-resistant and/or antisoil coating and the first polymer layer, or all layers, with regard to the particular refractive indices, are chosen so as to result in a minimization of reflection up to prevention of reflection.

In a very particular embodiment, the principle of simple antireflection coating coating can be obtained by virtue of the refractive index of the uppermost layer, with an accuracy of 5%, forming the square root of the refractive index of the layer below it.

Use of the Concentrators

The concentrators produced in accordance with the invention preferably find use as concentrators in photovoltaic plants or in solar heating plants. A distinction should be drawn between two different embodiments.

In a first embodiment, the lower side of the concentrator has angular or radial Fresnel lenses. These lead to point-concentrated focusing of solar radiation onto the two-dimensional geometry of a photovoltaic cell and onto a Stirling motor or thermal receiver of a solar thermal collector.

In a second embodiment, the lower side of the concentrator has linear Fresnel lenses. These can be used for linear-concentrated reflection of solar radiation onto a linear arrangement of photovoltaic cells, or onto an absorber tube of a solar thermal collector.

For both embodiments, it is possible to produce either flat panels or curved forms and instal them into the photovoltaic plant or solar thermal collector. Curving can be performed after the production of the concentrators and the subsequent cutting-to-size, for example by cold curving or thermoforming, preference being given to a cold curving process.

1. A process for producing a concentrator for solar power generation, the process comprising:
producing a high-transparency first polymer layer from a pellet formulation by melting in an extruder, withdrawing via a slot dieₛ and structuring a film surface with a gravure-bearing cooled roll or drum having a temperature gradient of at least 60° C. on a roll surface, on a later lower side of the concentrator,
wherein the high-transparency first polymer layer after the structuring has an optical surface structure on a lower side of the concentrator,
the optical surface structure forms one or more Fresnel lenses, and
the concentrator comprises a UV absorber and a UV stabilizer.

2. The process according to claim 1, further comprising:
applying a second polymer layer with coextrusion by a second extruder before the structuring from a second pellet formulation on an upper side of the high-transparency first polymer layer.

3. The process according to claim 2, further comprising:
applying a third polymer layer with coextrusion by the second or a third extruder on a lower side of the high-transparentcy first polymer layer before the structuring.

4. The process according to claim 2,
wherein the second polymer layer, an optional third polymer layer, or both the second polymer layer and optional third polymer layer is a multilayer coextrudate.

5. The process according to claim 1,
wherein the second polymer layer and an optional third polymer layer or at least one component layer of the second polymer layer and optional third polymer layer comprises the UV stabilizer and the UV absorber.

6. The process according to claim 1,
wherein the UV absorber is a triazine.

7. The process according to claim 1,
wherein the UV absorber comprises a benzotriazole and a triazine, and the UV stabilizer comprises a HALS compound.

8. The process according to claim 1, further comprising:
coating a surface of the concentrator with a scratch-resistant, antisoil coating, antireflection coating, or a combination thereof before the structuring.

9. The process according to claim 1,
wherein a refractive index of an uppermost layer, with an accuracy of 5%, forms a square root of a refractive index of a layer below it.

10. The process according to claim 1,
wherein the high-transparency first polymer layer is a transparent material.

11. The process according to claim 2,
wherein the second and an optional third polymer layer are each a layer of poly(meth)acrylate, a fluoropolymer, or a mixture of poly(meth)acrylate and a fluoropolymer.

12. A concentrator, comprising, viewed from the light source:
a second polymer layer comprising a UV stabilizer and a UV absorber and having a thickness between 5 and 500 μm,
a first polymer layer having a thickness between 0.1 and 25 mm,
wherein a lower side of the concentrator is surface-structured in a form of one or more Fresnel lenses.

13. The concentrator according to claim 12, comprising, viewed from the light source:
a surface finish with soil-repellent, antireflective, and scratch resistance-improving properties,
the second polymer layer,
the first polymer layer,
a third polymer layer with a thickness between 5 and 500 μm.

14. The concentrator according to claim 12,
wherein the one or more Fresnel lenses are each an angular, radialₛ or linear structure.

15. The concentrator according to claim 14,
wherein the one or more Fresnel lenses are arranged in grid or linear form, or irregularly with respect to one another.

16. A method, comprising point-concentrated focusing of solar radiation onto a two-dimensional geometry of a photovoltaic cell and a Stirling motor of a thermal receiver of a solar thermal collector, the method employing the concentrator according to claim 12,
wherein the concentrator comprises angular or radial Fresnel lenses.

17. A method, comprising linear-concentrated focusing of solar radiation onto a linear arrangement of photovoltaic cells or onto an absorber tube of a solar thermal collector, the method employing the concentrator according to claim 12,
wherein the concentrator comprises linear Fresnel lenses.

18. The process according to claim 10,
wherein the transparent material is at least one selected from the group consisting of SAN, polycarbonate, polyurethane, a polycycloolefin, polystyrene, a styrene copolymer, a polyester, and poly(meth)acrylate.

19. The process according to claim 11,
wherein the second and the optional third polymer layer are each a mixture of PMMA and PVDF or a multi-layer system composed of PMMA and PVDF.
